(19) United States
(12) Patent Application Publication
(10) Pub. No.: US 2025/0324893 A1
(43) Pub. Date: Oct. 16, 2025

(54) DISPLAY PANEL AND DISPLAY DEVICE

(71) Applicants: MIANYANG HKC OPTOELECTRONICS TECHNOLOGY CO., LTD., Mianyang (CN); HKC CORPORATION LIMITED, Shenzhen (CN)

(72) Inventors: QIN LIANG, Shenzhen (CN); Yangling Tang, Shenzhen (CN); Zhisheng Xie, Shenzhen (CN); Xiufeng Zhou, Shenzhen (CN); Lidan Ye, Shenzhen (CN)

(21) Appl. No.: 19/176,222

(22) Filed: Apr. 11, 2025

(30) Foreign Application Priority Data
Apr. 15, 2024 (CN) 202410451689.3

(51) Int. Cl. H10K 59/80; H10K 59/122

(52) U.S. Cl. CPC H10K 59/873; H10K 59/122

(57) ABSTRACT

A display panel and a display device are disclosed. The display panel includes a substrate, a pixel defining layer, multiple light-emitting elements, a conductive partition structure, a hygroscopic layer, and an encapsulation layer. The pixel defining layer is arranged on the substrate and has multiple openings. The multiple light-emitting elements are respectively arranged in the multiple openings. The conductive partition structure is arranged on the pixel defining layer. The hygroscopic layer is arranged on the conductive partition structure to absorb water vapor or oxygen. The encapsulation layer covers the multiple light-emitting elements and is used to seal the multiple light-emitting elements.

### CROSS-REFERENCE TO RELATED APPLICATIONS

This application claims the priority and benefit of Chinese patent application number 2024104516893, titled “Display Panel and Display Device” and filed Apr. 15, 2024 with China National Intellectual Property Administration, the entire contents of which are incorporated herein by reference.

### TECHNICAL FIELD

This application relates to the field of display technology, and more particularly relates to a display panel and a display device.

### BACKGROUND

The description provided in this section is intended for the mere purpose of providing background information related to the present application but does not necessarily constitute prior art.

Organic light-emitting diodes (OLEDs) have the advantages of surface light source, cold light, energy saving, fast response, flexibility, ultra-thinness, and low cost, and its mass production technology is becoming increasingly mature, so that OLED display panels are gradually becoming mainstream display panels. However, since the light-emitting devices in the OLED display panel have poor stability and are extremely sensitive to water and oxygen, which may cause the light-emitting devices to be oxidized and fail, the encapsulation technology is particularly critical. The purpose of encapsulation is mainly to prevent water vapor and air from entering the light-emitting device. However, due to processing reasons, on one hand the encapsulation layer may have cracks and other phenomena, which may allow external water vapor or oxygen to enter therefrom, and on the other hand the interface between the film layers may also allow external water vapor or oxygen to enter.

Relatively speaking, the current encapsulation layer can prevent water vapor or oxygen from entering, but it cannot absorb or remove water vapor or oxygen that may pass through the encapsulation layer. In view of this, the technical personnel in this field urgently need a technical solution.

### SUMMARY

It is therefore one purpose of this application to provide a display panel and a display device. By setting a hygroscopic layer on a conductive partition structure, the hygroscopic layer absorbs water vapor or oxygen entering the interior of the display panel to improve the encapsulation effect and display effect of the display panel.

This application discloses a display panel, which includes a substrate, a pixel defining layer, a plurality of light-emitting elements, a conductive partition structure, a hygroscopic layer, and an encapsulation layer. The pixel defining layer is disposed on the substrate and has a plurality of openings. The plurality of light-emitting elements are disposed in the plurality of openings respectively. The conductive partition structure is disposed on the pixel defining layer. The hygroscopic layer is disposed on the conductive partition structure and is used to absorb water vapor or oxygen. The encapsulation layer covers the plurality of light-emitting elements and is used to seal the plurality of light-emitting elements.

In some embodiments, the hygroscopic layer includes a porous organic film filled with desiccant particles. The desiccant particles include one or more selected from calcium oxide, aluminum oxide, iron oxide, activated carbon, graphene, or silica gel. The porous organic film includes one or more selected from organic photoresist or organic film.

In some embodiments, the light-emitting element includes a bottom electrode, a light-emitting layer, and a top electrode. The conductive partition structure includes a first metal layer and a first insulating layer. The first metal layer is disposed on the pixel defining layer. The first insulating layer is disposed on the first metal layer. The hygroscopic layer is disposed on the first insulating layer. The width of the first insulating layer is greater than the width of the first metal layer. The top electrodes of adjacent light-emitting elements are connected through the first metal layer.

In some embodiments, the width of the hygroscopic layer is smaller than the width of the first insulating layer.

In some embodiments, the encapsulation layer includes a first inorganic layer, an organic layer, and a second in-organic layer. The first inorganic layer covers the top electrode and the conductive partition structure. The first inorganic layer includes a groove corresponding to the location of the conductive partition structure, and the hygroscopic layer is disposed in the groove. The organic layer covers the first inorganic layer and the hygroscopic layer. The second inorganic layer is disposed on the organic layer.

In some embodiments, the thickness of the hygroscopic layer is greater than the thickness of the first inorganic layer. The width of the hygroscopic layer is less than the width of the first insulating layer.

In some embodiments, the angle between the side wall of the groove and the bottom surface of the groove is an obtuse angle, and the radial width of the groove gradually increases along the light-emitting direction. The hygroscopic layer partially covers the first inorganic layer. The maximum width of the hygroscopic layer is greater than the maximum width of the groove.

In some embodiments, the display panel includes a display area and a non-display area. The display panel further includes an encapsulation barrier dam, which is arranged in the non-display area. The encapsulation layer includes a first inorganic layer, an organic layer, and a second inorganic layer. The first inorganic layer and the second inorganic layer extend to the non-display area and cover the encapsulation barrier dam. The display panel further includes a hygroscopic extension portion. The hygroscopic layer is arranged in the display area, and the hygroscopic extension portion is arranged in the non-display area. The hygroscopic extension portion is arranged between the first inorganic layer and the second inorganic layer, and on the orthographic projection of the substrate, the hygroscopic extension portion overlaps or coincides with the encapsulation barrier dam.

In some embodiments, the hygroscopic extension portion and the hygroscopic layer are formed by the manufacturing same process.

This application further discloses a display device, including a driving circuit and the above-mentioned display panel, wherein the driving circuit is used to drive the display panel to display.

In this application, a hygroscopic layer is disposed on the conductive partition structure inside the display panel. The conductive partition structure is located on the pixel defining layer, i.e., located in a non-light-emitting area between pixels. Without affecting the display, the hygroscopic layer is disposed to absorb or consume the infiltrated water vapor or oxygen to prevent the water vapor or oxygen from entering and corroding the light-emitting element. Furthermore, even if one light-emitting element is corroded by water vapor or oxygen, the adjacent light-emitting element can be prevented from being further corroded, thereby improving the encapsulation effect of the display panel, and improving the reliability and display effect of the display panel in long-term use.

### BRIEF DESCRIPTION OF DRAWINGS

The accompanying drawings are used to provide a further understanding of the embodiments according to this application, and constitute a part of the specification. They are used to illustrate the embodiments according to this application, and explain the principles of this application in conjunction with the text description. Apparently, the drawings in the following description merely represent some embodiments of the present disclosure, and for those having ordinary skill in the art, other drawings may also be obtained based on these drawings without investing creative. In the drawings:

FIG. 1 is a schematic diagram of a display panel of a first embodiment of this application.

FIG. 2 is a top view of a display panel of the first embodiment of this application.

FIG. 3 is a schematic diagram of a display panel of a second embodiment of this application.

FIG. 4 is a schematic diagram of a display panel of a third embodiment of this application.

FIG. 5 is a schematic diagram of another display panel of the third embodiment of this application.

FIG. 6 is a schematic diagram of a display device of this application.

In the drawings: 100, display panel; 101, display area; 102, non-display area; 110, substrate; 111, pixel defining layer; 120, light-emitting element; 121, bottom electrode; 122, light-emitting layer; 123, top electrode; 130, conductive partition structure; 131, first metal layer; 132, first insulating layer; 140, hygroscopic layer; 141, hygroscopic extension portion; 150, encapsulation layer; 151, first inorganic layer; 151a, groove; 152, organic layer; 153, second inorganic layer; 160, encapsulation barrier dam; 200, display device; 210, driving circuit.

### DETAILED DESCRIPTION OF EMBODIMENTS

It should be understood that the terms used herein, the specific structures and functional details disclosed therein are merely representative for describing some specific embodiments, but this application can be implemented in many alternative forms and should not be construed as being limited to only these embodiments described herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. In addition, terms “up”, “down”, “left”, “right”, “vertical”, and “horizontal”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure. For those of ordinary skill in the art, the specific meanings of the above terms as used in this application can be understood depending on specific contexts.

This application will be described in detail below with reference to the accompanying drawings and some optional embodiments.

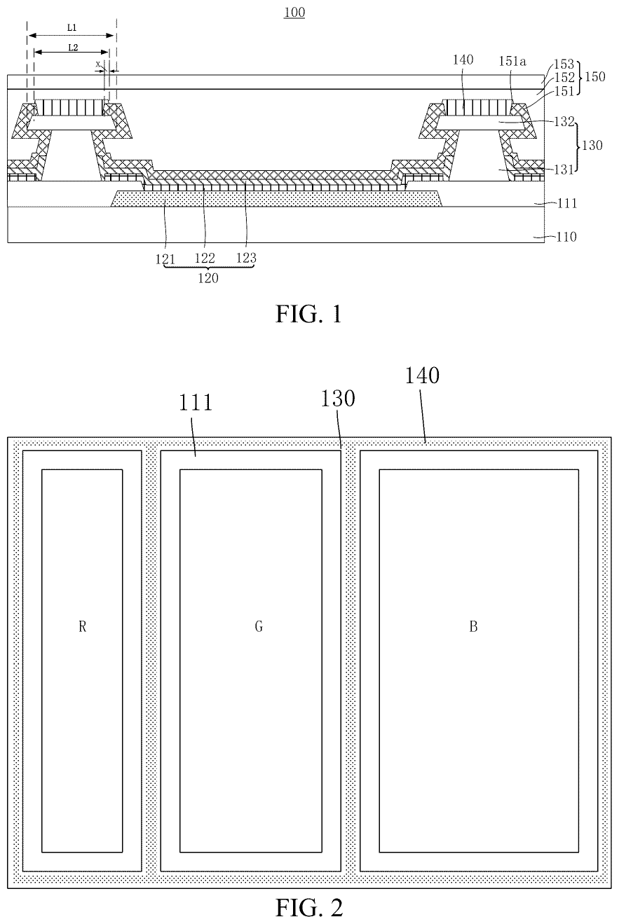

FIG. 1 is a schematic diagram of a display panel of a first embodiment of this application. As shown in FIG. 1, this application discloses a display panel 100. The display panel 100 includes a substrate 110, a pixel defining layer 111, a plurality of light-emitting elements 120, a conductive partition structure 130, a hygroscopic layer 140, and an encapsulation layer 150. The pixel defining layer 111 is disposed on the substrate 110 and defines a plurality of openings. The plurality of light-emitting elements 120 are respectively disposed in the plurality of openings. The conductive partition structure 130 is disposed on the pixel defining layer 111. The hygroscopic layer 140 is disposed on the conductive partition structure 130 for absorbing water vapor or oxygen. The encapsulation layer 150 covers the plurality of light-emitting elements 120 and is used to seal the plurality of light-emitting elements 120.

In this application, a hygroscopic layer 140 is disposed on the conductive partition structure 130 inside the display panel 100. The conductive partition structure 130 is located on the pixel defining layer 111, i.e., located in a non-light-emitting area between pixels. Without affecting the display, the hygroscopic layer 140 is disposed to absorb or consume the infiltrated water vapor or oxygen to prevent the water vapor or oxygen from entering and corroding the light-emitting element 120. Furthermore, even when one light-emitting element 120 is corroded by water vapor or oxygen, the adjacent light-emitting element 120 can be prevented from being further corroded, thereby improving the encapsulation effect of the display panel 100, and improving the reliability and display effect of the display panel 100 in long-term use.

In particular, the substrate 110 may be formed by a flexible substrate or a glass substrate. A pixel driving layer may be disposed on the substrate 110. The pixel driving layer may be formed by multiple metal layers and multiple insulating layers, and is mainly used to form metal wirings and thin film transistors and other components for driving the light-emitting element 120 to emit light. A planarization layer may be disposed on the pixel driving layer, and the main function of the planarization layer is to improve the surface flatness of the film layers. In this embodiment, the light-emitting element 120 and the pixel defining layer 111 are formed on the planarization layer.

The light-emitting element 120 may include a bottom electrode 121, a light-emitting layer 122, and a top electrode 123. The bottom electrode 121 is disposed on a planarization layer. The light-emitting layer 122 is disposed on the bottom electrode 121. The top electrode 123 is disposed on the light-emitting layer 122. The pixel defining layer 111 may be formed after the bottom electrodes 121 are patterned. A plurality of openings may be formed by etching at the positions of the pixel defining layer 111 corresponding to the bottom electrodes 121, and each opening corresponds to a respective light-emitting element 120.

In this embodiment, a conductive partition structure 130 is further formed on the pixel defining layer 111. The conductive partition structure 130 is also called an eaves structure or a hanging structure, and its main structure includes a first metal layer 131 arranged at the bottom and a first insulating layer 132 arranged at the top. The first metal layer 131 contacts the pixel defining layer 111 and is disposed on the pixel defining layer 111. The width of the first insulating layer 132 is greater than the width of the first metal layer 131, thereby forming a structure similar to an eaves.

In this application, the conductive partition structure 130 is a maskless evaporation technology, which is mainly used when forming the light-emitting layer 122 and the top electrode 123. By using the conductive partition structure 130, partitions are formed at non-opening positions when forming the light-emitting layer 122, and no mask plate is required for etching, etc., which is called maskless evaporation. Furthermore, the lower part of the overhanging structure is formed of a metal material, which has conductive properties and can connect the top electrodes 123 of the multiple light-emitting elements 120 to form a full-surface wiring of the top electrodes 123, thereby reducing the resistance of the top electrode 123. It is worth mentioning that the bottom electrode 121 in the light-emitting element 120 may be formed of ITO/Ag/ITO materials, and the top electrode 123 may be formed of ITO, Mg, Ag or an alloy of Mg and Ag. The top electrodes 123 of adjacent light-emitting elements 120 may be connected through the first metal layer 131 in the conductive partition structure 130.

In one embodiment, the width L2 of the hygroscopic layer 140 is smaller than the width L1 of the first insulating layer 132. Since the edge of the first insulating layer 132 belongs to the light-emitting area, and when the hygroscopic layer 140 is disposed in the light-emitting area, it is easy to block the emitted light. Therefore, the width of the hygroscopic layer 140 is set smaller than the width of the first insulating layer 132, so as not to affect the light-emitting area, that is, the opening area.

The OLED display panel 100 may include a white light-emitting element 120 or an RGB light-emitting element 120. The white light-emitting element 120 means that the light emitted by the light-emitting element 120 in the display panel 100 is white light. In this case, the light-emitting layers 122 of all the light-emitting elements 120 may be formed of the same material. As for the RGB light-emitting elements 120, the light-emitting elements 120 in the display panel 100 may be divided into three types, such as red light-emitting element 120, green light-emitting element 120, and blue light-emitting element 120. The light-emitting layers 122 of the three colors of light-emitting elements 120 use different materials. Therefore, in the manufacturing process, light-emitting elements 120 of different colors need to be manufactured in different steps. For example, after forming the red light-emitting element 120, the green light-emitting element 120 may be formed, and finally the blue light-emitting element 120 may be formed.

In particular, the encapsulation layer 150 may include a first inorganic layer 151, an organic layer 152, and a second inorganic layer 153. The encapsulation of the light-emitting element 120 is achieved by stacking multiple inorganic layers and the organic layer 152. The first inorganic layer 151 covers the light-emitting element 120 and the conductive partition structure 130. The organic layer 152 covers the first inorganic layer 151. The second inorganic layer 153 covers the organic layer 152.

Since the RGB light-emitting elements 120 need to be formed in steps, after the red light-emitting element 120 is formed, the first inorganic layer 151 is formed at the position where the red light-emitting element 120 is formed. The first inorganic layer 151 is used to protect the red light-emitting element 120 below to prevent the subsequent formation of light-emitting elements 120 of other colors from affecting the red light-emitting element 120. Of course, the first inorganic layer 151 may also be only disposed to cover the red light-emitting element 120. After completing all the manufacturing processes of the light-emitting elements 120, a complete first inorganic layer 151 may be formed.

In particular, the first inorganic layer 151 defines a groove 151a corresponding to the position of the conductive partition structure 130. The hygroscopic layer 140 is disposed in the groove 151a. The organic layer 152 covers the first inorganic layer 151 and the hygroscopic layer 140.

In this solution, the groove 151a is formed in the process of forming the light-emitting element 120. The hygroscopic layer 140 is formed by utilizing the position of the groove 151a. The location of the hygroscopic layer 140 can absorb water vapor or oxygen entering from the cracks of the first inorganic layer 151 and the organic layer 152 or the film interface to the maximum extent. Without affecting the encapsulation effect of the first inorganic layer 151, the organic layer 152, and the second inorganic layer 153 in the encapsulation layer 150, the water vapor or oxygen entering through the encapsulation layer 150 can be absorbed to improve the encapsulation effect of the display panel 100.

Of course, for the white light-emitting element 120, the first inorganic layer 151 does not have a groove 151a at the location of the conductive partition structure 130. In this case, the hygroscopic layer 140 may be disposed on the first inorganic layer 151.

The thickness of the hygroscopic layer 140 is greater than the thickness of the first inorganic layer 151. The greater the thickness of the hygroscopic layer 140, the stronger the corresponding ability to absorb water vapor or oxygen. However, relatively speaking, since the film thicknesses of the conductive partition structure 130, the first inorganic layer 151, the organic layer 152, and the second inorganic layer 153 are relatively fixed, the maximum thickness of the hygroscopic layer 140 cannot be higher than the surface of the organic layer 152.

On the basis of the above, the width of the hygroscopic layer 140 is smaller than the width of the first insulating layer 132, and the width of the hygroscopic layer 140 is greater than or equal to the width of the first metal layer 131.

FIG. 2 is a schematic top view of a display panel of the first embodiment of this application. As shown in FIG. 2, each light-emitting element 120 may form a sub-pixel. A plurality of conductive partition structures 130 are arranged around a sub-pixel. At least one circle of conductive partition structures 130 is arranged around each sub-pixel. A circle of hygroscopic layer 140 is arranged on the conductive partition structure 130.

In particular, the angle between the side wall of the groove 151a and the bottom surface is an obtuse angle. The radial width of the groove 151a gradually increases along the light-emitting direction. The hygroscopic layer 140 partially covers the first inorganic layer 151 (see x greater than 0 in FIG. 1).

In this solution, the groove 151a has an inclined inner wall, and the radial width of the groove 151a gradually increases along the light-emitting direction. The groove 151a is formed by etching, and accordingly, an inclined inner wall is naturally formed on the inner wall of the groove 151a. Furthermore, the inclined inner wall is covered with a hygroscopic structure, and at the edge position of the first inorganic layer 151 at the groove 151a, the hygroscopic layer 140 also covers the edge position. In other words, on the orthographic projections of the substrate 110, the hygroscopic layer 140 partially overlaps or coincides with the first inorganic layer 151 at the groove 151a. It may be understood that the light-emitting direction refers to the direction from the bottom electrode 121 toward the top electrode 123 in the light-emitting element 120, which may be understood as that the direction perpendicular to the substrate 110 and pointing toward the light-emitting element 120 is the light-emitting direction.

The maximum width of the hygroscopic layer 140 is greater than the maximum width of the groove 151a.

In particular, the hygroscopic layer 140 includes a porous organic film filled with desiccant particles The desiccant particles are filled in the porous structure of the organic film. The desiccant particles may include water vapor or oxygen absorbing materials such as calcium oxide, aluminum oxide, activated carbon, graphene, or silica gel, or reactive materials such as iron oxide that react chemically with water vapor and oxygen. In particular, one or more of them can be selected depending on actual conditions. The organic film can be formed of an organic photoresist material or an organic film material. When an organic photoresist material is selected, the hygroscopic layer 140 of the groove 151a can be formed by photolithography patterning. When an organic film material is selected, the hygroscopic layer 140 may be fixed to the first insulating layer 132 by bonding and curing.

The organic film in the hygroscopic layer 140 may also be made of a black light-absorbing material, and the width may be set to be greater than the first metal layer to block the ambient light from directly hitting the first metal layer, eliminate the ambient light produced on the first metal layer from interfering with the display, and improve the contrast of the product.

In this solution, by using the hygroscopic layer 140 of the black light-absorbing material, it is possible to prevent external ambient light from entering the display panel 100 to a certain extent and reflecting the ambient light by the first metal layer 131 in the conductive partition structure 130 thus causing light reflection and other phenomena and affecting the display effect of the display panel 100. In this solution, the hygroscopic layer 140 with a light shielding function is disposed on the conductive partition structure 130, so as to absorb water vapor and prevent the reflection of ambient light.

In this embodiment, the conductive partition structure 130 is mainly used to form a hygroscopic layer 140 of a certain thickness at the groove 151a position of the first inorganic layer 151. Without affecting the display, the hygroscopic layer 140 is disposed to absorb or consume the infiltrated water vapor or oxygen to prevent the water vapor or oxygen from entering and corroding the light-emitting element 120. Furthermore, even if one light-emitting element 120 is corroded by water vapor or oxygen, the adjacent light-emitting element 120 can be prevented from being further corroded, thereby improving the encapsulation effect of the display panel 100, and improving the reliability and display effect of the display panel 100 in long-term use. In addition, by setting a hygroscopic layer 140 above the conductive partition structure 130, the hygroscopic layer 140 has a certain light absorption effect, which can prevent the first metal layer 131 in the conductive partition structure 130 from reflecting ambient light and causing light reflection, thereby improving the display effect of the display panel 100.

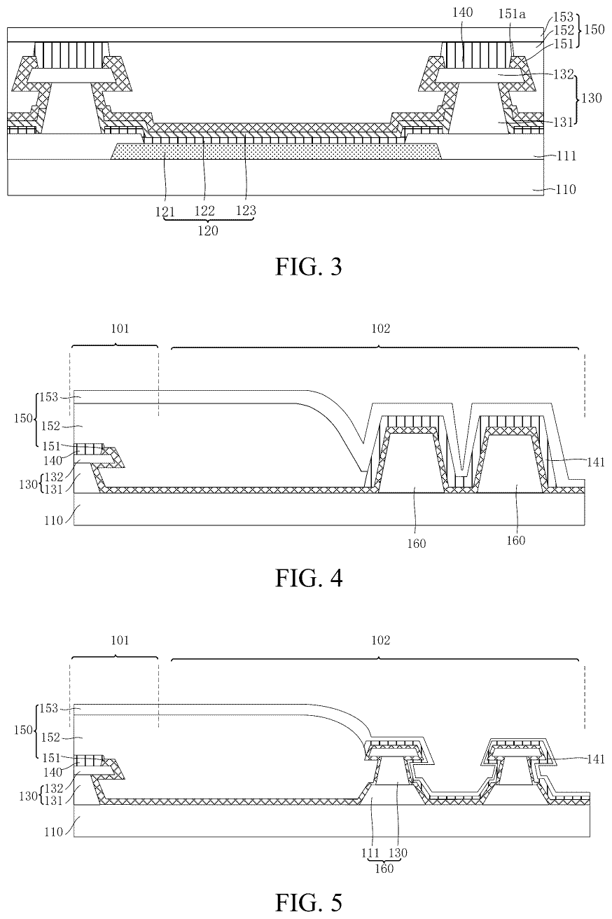

FIG. 3 is a schematic diagram of a display panel of a second embodiment of this application. As shown in FIG. 3, based on the first embodiment, the thickness of the hygroscopic layer 140 is further increased in this embodiment, so that the hygroscopic layer 140 forms a partition for the organic layer 152.

In particular, the first inorganic layer 151 covers the top electrode 123 and the conductive partition structure 130. The first inorganic layer 151 defines a groove 151a corresponding to the location of the conductive partition structure 130, and the hygroscopic layer 140 is disposed in the groove 151a. The organic layer 152 covers the first inorganic layer 151, and at the location corresponding to the hygroscopic layer 140 there is not disposed an organic layer 152, or there is disposed a thinner organic layer. The second inorganic layer 153 is disposed on the organic layer 152 and the hygroscopic layer 140.

The inorganic layer in the encapsulation layer 150 may have a high water and oxygen barrier capability, and may be a silicon nitride (SiNX) inorganic film or a silicon oxynitride (SiOXNy) inorganic film prepared by plasma-enhanced chemical vapor deposition (PECVD) technology. The organic layer 152 mainly refers to a transparent polymer film prepared by inkjet printing (IJP) technology, which has relatively high defect coverage and stress buffering performance, and is mainly used to buffer the stress between inorganic layers and compensate for film defects.

In this solution, by setting a hygroscopic layer 140 of an organic film material, the organic layer 152 above the conductive partition structure 130 can be eliminated. The hygroscopic layer 140 can be used to block the water vapor propagation path in the organic layer 152, so that each light-emitting element 120 forms an independent encapsulation structure to prevent water vapor or oxygen from invading therein, further improving the encapsulation capability of the display panel 100.

FIG. 4 is a schematic diagram of a display panel of a third embodiment of this application. As shown in FIG. 4, this application further discloses a display panel 100. The display panel 100 includes a display area 101 and a non-display area 102. In the display area 101, the display panel 100 includes a pixel defining layer 111, a plurality of light-emitting elements 120, a conductive partition structure 130, and a hygroscopic layer 140. The pixel defining layer 111 is disposed on the substrate 110 and defines a plurality of openings. The plurality of light-emitting elements 120 are respectively disposed in the plurality of openings. The conductive partition structure 130 is disposed on the pixel defining layer 111. The hygroscopic layer 140 is disposed on the conductive partition structure 130 and is used to absorb water vapor or oxygen. The encapsulation layer 150 is disposed to cover the plurality of light-emitting elements 120 and is used to seal the plurality of light-emitting elements 120. In the non-display area 102, the display panel 100 further includes an encapsulation barrier dam 160, which is disposed in the non-display area 102. The encapsulation layer 150 extends from the display area 101 to the non-display area 102. In particular, the encapsulation layer 150 includes a first inorganic layer 151, an organic layer 152, and a second inorganic layer 153. The first inorganic layer 151 and the second inorganic layer 153 extend to the non-display area 102 and cover the encapsulation barrier dam 160.

The display panel 100 further includes a hygroscopic extension portion 141. The hygroscopic layer 140 is disposed in the display area 101. The hygroscopic extension portion 141 is disposed in the non-display area 102. The hygroscopic extension portion 141 is disposed between the first inorganic layer 151 and the second inorganic layer 153, and on the orthographic projection of the substrate 110, the hygroscopic extension portion 141 overlaps or coincides with the encapsulation barrier dam 160.

Since the organic layer 152 is not disposed in the area where the encapsulation barrier dam 160 is located to buffer the stress of the first inorganic layer 151 and the second inorganic layer 153, cracks are likely to occur in the first inorganic layer 151 or the second inorganic layer 153 in the area where the encapsulation barrier dam 160 is located. In this solution, the hygroscopic extension portion 141 is disposed in the area where the encapsulation barrier dam 160 is located, and is disposed between the first inorganic layer 151 and the second inorganic layer 153. On the one hand, the hygroscopic layer 140 made of an organic film material has a certain deformation ability, which is conducive to releasing the stress between the first inorganic layer 151 and the second inorganic layer 153 on the encapsulation barrier dam 160, alleviating the micro cracks of the first inorganic layer 151 and the second inorganic layer 153 at the location of the encapsulation barrier dam 160 at the climbing position, and preventing the first inorganic layer 151 from extending to the second inorganic layer 153 when cracks are generated. Furthermore, the hygroscopic extension portion 141 further has a certain function of absorbing water vapor or oxygen, and can prevent water vapor or oxygen from invading the inside of the display panel 100 as much as possible.

It is worth mentioning that the hygroscopic extension portion 141 in this embodiment may be formed of the same material as that of the hygroscopic layer 140. In particular, the hygroscopic extension portion 141 and the hygroscopic layer 140 may be formed by the same manufacturing process.

In this embodiment, the hygroscopic extension portion 141 totally covers the encapsulation barrier layer. In the case where multiple encapsulation barrier dams 160 are disposed, the hygroscopic extension portion 141 may not be disposed in the area between two encapsulation barrier dams 160.

In another embodiment, a plurality of hygroscopic extension portions 141 may be disposed, each of which is only disposed at the corner positions of the encapsulation barrier dam 160. The corner position refers to the film layer change position of the encapsulation barrier dam 160, such as the starting point and the end point of a slope.

FIG. 5 is a schematic diagram of another display panel of the third embodiment of this application. In this embodiment, the encapsulation barrier dam 160 may be composed of two or more layers selected from the group of a planarization layer, a pixel defining layer 111, and a conductive partition structure 130. For example, the pixel defining layer 111 may be synchronously formed with the manufacturing process of the display area 101, and the conductive partition structure 130 may be formed on the pixel defining layer 111. At this time, the encapsulation barrier dam 160 may be formed by the pixel defining layer 111 and the conductive partition structure 130. By making the width of the first insulating layer 132 located at the upper part of the conductive partition structure 130 greater than the width of the first metal layer 131 located at the lower part, the first inorganic layer 151 and the second inorganic layer 153 have a relatively tortuous path on the conductive partition structure 130, thereby extending the path for water vapor or oxygen to invade. Furthermore, the conductive partition structure 130 is a key structure used in the maskless evaporation technology, and can be processed synchronously with other overhanging structures in the display panel 100, so that better encapsulation is achieved without adding additional manufacturing processes and without adding additional costs.

In this embodiment, the conductive partition structure 130 is mainly used to form a hygroscopic layer 140 of a certain thickness at the groove 151a position of the first inorganic layer 151. Without affecting the display, the hygroscopic layer 140 is disposed to absorb or consume the infiltrated water vapor or oxygen to prevent the water vapor or oxygen from entering and corroding the light-emitting element 120. Furthermore, even if one light-emitting element 120 is corroded by water vapor or oxygen, the adjacent light-emitting element 120 can be prevented from being further corroded, thereby improving the encapsulation effect of the display panel 100, and improving the reliability and display effect of the display panel 100 in long-term use. In addition, by setting a hygroscopic layer 140 above the conductive partition structure 130, the hygroscopic layer 140 has a certain light absorption effect, which can prevent the first metal layer 131 in the conductive partition structure 130 from reflecting ambient light and causing light reflection, thereby improving the display effect of the display panel 100. The hygroscopic extension portion 141 is arranged in the area where the encapsulation barrier dam 160 is located, and is arranged between the first inorganic layer 151 and the second inorganic layer 153. On the one hand, the hygroscopic layer 140 made of an organic film material has a certain deformation ability, which is conducive to releasing the stress between the first inorganic layer 151 and the second inorganic layer 153 on the encapsulation barrier dam 160, alleviating the micro cracks of the first inorganic layer 151 and the second inorganic layer 153 at the location of the encapsulation barrier dam 160 at the climbing position, and preventing the first inorganic layer 151 from extending to the second inorganic layer 153 when cracks are generated. Furthermore, the hygroscopic extension portion 141 also has a certain function of absorbing water vapor or oxygen, and can prevent water vapor or oxygen from invading the inside of the display panel 100 as much as possible. Furthermore, the hygroscopic extension portion 141 and the hygroscopic layer 140 can be formed simultaneously, and the encapsulation effect of the display panel 100 is further improved without adding additional processes.

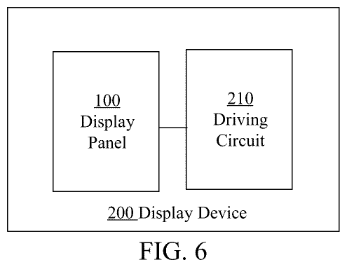

FIG. 6 is a schematic diagram of a display device of this application. As shown in FIG. 6, this application discloses a display device. The display device 200 includes a driving circuit 210 and any one of the display panels 100 in the above-mentioned embodiments 1, 2, and 3. The driving circuit 210 is used to drive the display panel 100 for display.

It should be noted that the inventive concept of this application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of this application with reference to some specific optional implementations, but it cannot be determined that the specific implementation of this application is limited to these implementations. For those having ordinary skill in the technical field to which this application pertains, several deductions or substitutions may be made without departing from the concept of this application, and all these deductions or substitutions should be regarded as falling in the scope of protection of this application.

What is claimed is:

1. A display panel, comprising:
a substrate;
a pixel defining layer, disposed on the substrate and comprising a plurality of openings;
a plurality of light-emitting elements, respectively disposed in the plurality of openings;
a conductive partition structure, disposed on the pixel defining layer;
a hygroscopic layer, disposed on the conductive partition structure and used for absorbing water vapor or oxygen; and
an encapsulation layer, covering the plurality of light-emitting elements and used for sealing the plurality of light-emitting elements.

2. The display panel as recited in claim 1, wherein the hygroscopic layer comprises a porous organic film filled with desiccant particles;
wherein the desiccant particles comprise one or more selected from the group consisting of calcium oxide, aluminum oxide, iron oxide, activated carbon, graphene, or silica gel; and wherein the porous organic film comprises one or more selected from the group consisting of an organic photoresist or an organic film.

3. The display panel as recited in claim 1, wherein each of the plurality of light-emitting elements comprises a bottom electrode, a light-emitting layer, and a top electrode;
wherein the conductive partition structure comprises a first metal layer and a first insulating layer, wherein the first metal layer is disposed on the pixel defining layer, wherein the first insulating layer is disposed on the first metal layer, wherein the hygroscopic layer is disposed on the first insulating layer, and wherein the first insulating layer has a width that is greater than a width of the first metal layer;
wherein the top electrodes of adjacent light-emitting elements are connected through the first metal layer.

4. The display panel as recited in claim 3, wherein the hygroscopic layer has a width that is smaller than a width of the first insulating layer.

5. The display panel as recited in claim 2, wherein the encapsulation layer comprises a first inorganic layer, an organic layer, and a second inorganic layer;
wherein the first inorganic layer is disposed to cover the top electrode and the conductive partition structure;
wherein the first inorganic layer comprises a groove corresponding to a position of the conductive partition structure, and wherein the hygroscopic layer is disposed in the groove;
wherein the organic layer is disposed to cover the first inorganic layer and the hygroscopic layer;
wherein the second inorganic layer is disposed on the organic layer.

6. The display panel as recited in claim 5, wherein a thickness of the hygroscopic layer is greater than a thickness of the first inorganic layer; wherein a width of the hygroscopic layer is less than a width of the first insulating layer.

7. The display panel as recited in claim 5, wherein an angle formed between a side wall of the groove and a bottom surface of the groove is an obtuse angle,
wherein a radial width of the groove gradually increases along a light-emitting direction of the display panel; wherein the hygroscopic layer partially covers the first inorganic layer;
wherein a maximum width of the hygroscopic layer is greater than a maximum width of the groove.

8. The display panel as recited in claim 1, wherein the display panel comprises a display area and a non-display area, and wherein the display panel further comprises an encapsulation barrier dam arranged in the non-display area;
wherein the encapsulation layer comprises a first inorganic layer, an organic layer, and a second inorganic layer; wherein the first inorganic layer and the second inorganic layer extend to the non-display area and cover the encapsulation barrier dam;
wherein the display panel further comprises a hygroscopic extension portion, wherein the hygroscopic layer is disposed in the display area and wherein the hygroscopic extension portion is disposed in the non-display area;
wherein the hygroscopic extension portion is disposed between the first inorganic layer and the second organic layer, and wherein an orthogonal projection of the hygroscopic extension portion on the substrate overlaps or coincides with an orthogonal projection of the encapsulation barrier dam on the substrate.

9. The display panel as recited in claim 8, wherein the hygroscopic extension portion and the hygroscopic layer are formed by one same manufacturing process.

10. The display panel as recited in claim 1, wherein a plurality of the conductive partition structures are arranged around one respective sub-pixel, and wherein the hygroscopic layer is arranged on the conductive partition structure in a circle around the respective sub-pixel.

11. The display panel as recited in claim 3, wherein the first inorganic layer is disposed to cover the top electrode and the conductive partition structure; wherein the first inorganic layer comprises a groove corresponding to a position of the conductive partition structure, and wherein the hygroscopic layer is disposed in the groove; wherein the organic layer is disposed to cover the first inorganic layer;
wherein the second inorganic layer is disposed on the organic layer and the hygroscopic layer.

12. A display device, comprising a driving circuit and a display panel, wherein the driving circuit is used to drive the display panel to display; wherein the display panel comprises:
a substrate;
a pixel defining layer, disposed on the substrate and comprising a plurality of openings;
a plurality of light-emitting elements, respectively disposed in the plurality of openings;
a conductive partition structure, disposed on the pixel defining layer;
a hygroscopic layer, disposed on the conductive partition structure and used for absorbing water vapor or oxygen; and
an encapsulation layer, covering the plurality of light-emitting elements and used for sealing the plurality of light-emitting elements.

13. The display device as recited in claim 12, wherein the hygroscopic layer comprises a porous organic film filled with desiccant particles;
wherein the desiccant particles comprise one or more selected from the group consisting of calcium oxide, aluminum oxide, iron oxide, activated carbon, graphene, or silica gel; and wherein the porous organic film comprises one or more selected from the group consisting of an organic photoresist or an organic film.

14. The display device as recited in claim 12, wherein each of the plurality of light-emitting elements comprises a bottom electrode, a light-emitting layer, and a top electrode;
wherein the conductive partition structure comprises a first metal layer and a first insulating layer, wherein the first metal layer is disposed on the pixel defining layer, wherein the first insulating layer is disposed on the first metal layer, wherein the hygroscopic layer is disposed on the first insulating layer, and wherein the first insulating layer has a width that is greater than a width of the first metal layer;
wherein the top electrodes of adjacent light-emitting elements are connected through the first metal layer.

15. The display device as recited in claim 14, wherein a width of the hygroscopic layer is less than a width of the first insulating layer.

16. The display device as recited in claim 14, wherein the encapsulation layer comprises a first inorganic layer, an organic layer, and a second inorganic layer;
wherein the first inorganic layer is disposed to cover the top electrode and the conductive partition structure;
wherein the first inorganic layer comprises a groove corresponding to a position of the conductive partition structure, and wherein the hygroscopic layer is disposed in the groove;
wherein the organic layer is disposed to cover the first inorganic layer and the hygroscopic layer;
wherein the second inorganic layer is disposed on the organic layer.

17. The display device as recited in claim 16, wherein a thickness of the hygroscopic layer is greater than a thickness of the first inorganic layer; wherein a width of the hygroscopic layer is less than a width of the first insulating layer.

18. The display device as recited in claim 16, wherein an angle formed between a side wall of the groove and a bottom surface of the groove is an obtuse angle, wherein a radial width of the groove gradually increases along a light-emitting direction of the display panel; wherein the hygroscopic layer partially covers the first inorganic layer;
wherein a maximum width of the hygroscopic layer is greater than a maximum width of the groove.

19. The display device as recited in claim 12, wherein the display panel comprises a display area and a non-display area, and wherein the display panel further comprises an encapsulation barrier dam arranged in the non-display area;
wherein the encapsulation layer comprises a first inorganic layer, an organic layer, and a second inorganic layer; wherein the first inorganic layer and the second inorganic layer extend to the non-display area and cover the encapsulation barrier dam;
wherein the display panel further comprises a hygroscopic extension portion, wherein the hygroscopic layer is disposed in the display area and wherein the hygroscopic extension portion is disposed in the non-display area;
wherein the hygroscopic extension portion is disposed between the first inorganic layer and the second organic layer, and wherein an orthogonal projection of the hygroscopic extension portion on the substrate overlaps or coincides with an orthogonal projection of the encapsulation barrier dam on the substrate.
